(19) United States
(12) Patent Application Publication
(10) Pub. No.: US 2014/0203383 A1
(43) Pub. Date: Jul. 24, 2014

(54) PERPENDICULAR MAGNETORESISTIVE MEMORY ELEMENT

(71) Applicant: Yimin Guo, San Jose, CA (US)

(72) Inventor: Yimin Guo, San Jose, CA (US)

(73) Assignee: T3MEMORY, INC., Saratoga, CA (US)

(21) Appl. No.: 14/162,715

(22) Filed: Jan. 23, 2014

Related U.S. Application Data
(60) Provisional application No. 61/756,425, filed on Jan. 24, 2013.

(51) Int. Cl. H01L 43/02

(52) U.S. Cl. CPC H01L 43/02
USPC 257/421

(57) ABSTRACT

A perpendicular magnetoresistive memory element comprises a three-terminal structure having a thick multilayered recording layer connected to a middle electrode and a functional layer having rocksalt crystal structure interfacing to the recording layer. The interface crystal grain structures between the functional layer and the recording layer provides an electric field manipulated perpendicular anisotropy enabling a low spin transfer write current.

### RELATED APPLICATIONS

This application claims the priority benefit of U.S. Provisional Application No. 61,756,425, filed Jan. 24, 2013, which is incorporated herein by reference.

### BACKGROUND OF THE INVENTION

1. Field of the Invention

This invention relates to the field of perpendicular magnetoresistive elements. More specifically, the invention comprises perpendicular spin-transfer-torque magnetic-random-access memory (MRAM) using perpendicular magnetoresistive elements as basic memory cells which potentially replace the conventional semiconductor memory used in electronic chips, especially mobile chips for power saving and non-volatility.

2. Description of the Related Art

In recent years, magnetic random access memories (hereinafter referred to as MRAMs) using the magnetoresistive effect of ferromagnetic tunnel junctions (also called MTJs) have been drawing increasing attention as the next-generation solid-state non-volatile memories that can cope with high-speed reading and writing, large capacities, and low-power-consumption operations. A ferromagnetic tunnel junction has a three layer stack structure formed by stacking a recording layer having a changeable magnetization direction, an insulating spacing layer, and a fixed layer that is located on the opposite side from the recording layer and maintains a predetermined magnetization direction.

As a write method to be used in such magnetoresistive elements, there has been suggested a write method (spin torque transfer switching technique) using spin momentum transfers. According to this method, the magnetization direction of a recording layer is reversed by applying a spin-polarized current to the magnetoresistive element. Furthermore, as the volume of the magnetic layer forming the recording layer is smaller, the injected spin-polarized current to write or switch can be also smaller. Accordingly, this method is expected to be a write method that can achieve both device miniaturization and lower currents.

Further, as in a so-called perpendicular MTJ element, both two magnetization films have easy axis of magnetization in a direction perpendicular to the film plane due to their strong magnetic crystalline anisotropy, shape anisotropies are not used, and accordingly, the device shape can be made smaller than that of an in-plane magnetization type. Also, variance in the easy axis of magnetization can be made smaller. Accordingly, y using a material having a large magnetic crystalline anisotropy, both miniaturization and lower currents can be expected to be achieved while a thermal disturbance resistance is maintained.

In order to obtain perpendicular magnetization of a recording layer with enough thermal stability, one typical method is that the recording layer is ferromagnetically coupled to additional perpendicular magnetization layer, such as TbCoFe, or CoPt, or multilayer such as (Co/Pt)n, to obtain enough crystal perpendicular anisotropy. Doing so, reduction in write current becomes difficult due to the fact that damping constant increases from the additional perpendicular magnetization layer and its associated seed layer for crystal lattice matching and material diffusion during the heat treatment in the device manufacturing process. Since in a spin injection MRAM, a spin transfer write current is proportional to the damping constant and inversely proportional to a spin polarization, reduction of the damping constant, increasing of the spin polarization and maintaining of the perpendicular anisotropy are mandatory technologies to reduce the write current. But, the materials of the recording layer typically used in an in-plane MTJ for both low damping constant and high MR as required by low write current application normally don't have enough magnetic crystalline anisotropy to achieve thermally stable perpendicular magnetization against its demagnetization field.

There has been a known technique for achieving a high spin polarization and MR ratio by forming a crystallization acceleration film that accelerates crystallization and is in contact with an interfacial magnetic film having an amorphous structure. As the crystallization acceleration film is formed, crystallization is accelerated from the tunnel barrier layer side, and the interfaces with the tunnel barrier layer and the interfacial magnetic film are matched to each other. By using this technique, a high MR ratio can be achieved. Further, a recording layer consisting of CoFeB (with B content no less than 15%) layer, which is in an amorphous state as deposited, is made adjacent to a functional layer consisting of an MgO layer, a surface perpendicular anisotropy can be readily formed thereof will be described later.

The MgO functional layer is formed into rocksalt crystal grains with the (100) plane parallel to the substrate plane. In the rocksalt crystal structure, two fcc sublattices for Mg and O, each displaced with respect to the other by half lattice parameter along the [100] direction. Its lattice parameter along the {110} direction is ranged from 2.98 to 3.02 angstrom, which has slightly larger than bcc CoFe lattice parameter along {100} direction and has a lattice mismatch between 4% and 7%. After thermal annealing with a temperature higher than 250-degree, the amorphous CoFeB is crystallized to form bcc CoFe grains having epitaxial growth with (100) plane parallel to surface of the rocksalt crystal functional layers. Accordingly, a surface perpendicular anisotropy is induced in the recording layer. Further, as an electric field is applied on the functional layer and perpendicular to the surface, the negative charged O atoms and positive charged metal atoms at surface are pulled toward opposite directions and modify the interface interaction between the bcc CoFe grains in the soft adjacent layer and the rocksalt crystal grains in the functional layer. When an electric field points down towards the top surface of a functional layer, O atoms protrude more from the surface and form a stronger interface interaction with the bcc CoFe grains, causing an enhanced perpendicular anisotropy, and vice versa. This mechanism is utilized hereafter to manipulate the surface perpendicular anisotropy strength and magnetization direction of the recording layer through applying an electric field on the dielectric functional layer, especially a reduction of surface perpendicular anisotropy can directly lead to a much reduced spin transfer current during a write operation.

However, above described electric field assisted writing requires a three-terminal architecture in an MRAM memory cell having a recording as a middle terminal. A process to make a good electric connection from the middle terminal to outside electrode typically demands a relative thick recording layer, which is mandatory and becomes a processing challenge to an electric field assisted spin transfer MRAM.

### BRIEF SUMMARY OF THE PRESENT INVENTION

The present invention comprises perpendicular magnetoresistive element for perpendicular spin-transfer-torque MRAM. The perpendicular magnetoresistive element in the invention has an MTJ stack including an anisotropy functional layer which is sandwiched between an upper electrode and a lower electrode of each MRAM memory cell and has a recording layer connected to a select transistor via a middle electrode, which also comprises a control circuitry which supplies a voltage drop, or an electric field on a functional layer between the transistor and the bottom electrode, and supplies a bidirectional spin transfer current between the transistor and the upper electrode.

The invention includes a magnetoresistive element comprising: a recording layer having magnetic anisotropy in a direction perpendicular to a film surface and having a variable magnetization direction; a reference layer having magnetic anisotropy in a direction perpendicular to a film surface and having an invariable magnetization direction; a tunnel barrier layer provided between the recording layer and the reference layer; and a functional layer provided on a surface of the recording layer, which is opposite to a surface of the recording layer where the tunnel barrier layer is provided, wherein the functional layer contains a rocksalt crystal structure having the (100) plane parallel to the substrate plane and with lattice parameter along its {110} direction being slightly larger than the bcc(body-centered cubic)-phase Co lattice parameter along {100} direction.

An exemplary embodiment includes a recording layer consisting of a multilayer structure having a first ferromagnetic sub-layer immediately adjacent to the tunnel barrier layer, a second amorphous ferromagnetic sub-layer immediately adjacent to the rocksalt crystal functional layer, an optional middle ferromagnetic sub-layer having a crystal perpendicular anisotropy.

Another exemplary embodiment includes a conductive buffer layer between a recording layer and a functional layer and consisting of a super-lattice structure having a strong surface interactions with both the functional and the recording layer.

The invention preferably includes materials and configurations of perpendicular magnetoresistive elements.

### BRIEF DESCRIPTION OF THE DRAWINGS

FIG. 1 is a cross-sectional view showing a configuration of an MTJ element 10 according to the first embodiment;

FIG. 2 is a cross-sectional view showing a configuration of an MTJ element 10 according to the second embodiment;

FIG. 3 is a cross-sectional view showing a configuration of an MTJ element 10 according to the third embodiment;

FIG. 4 is a cross-sectional view showing a configuration of an MTJ element 10 according to the fourth embodiment;

### DETAILED DESCRIPTION OF THE INVENTION

In general, according to one embodiment, there is provided a magnetoresistive element comprising:
a recording layer having magnetic anisotropy in a direction perpendicular to a film surface and having a variable magnetization direction;
a reference layer having magnetic anisotropy in a direction perpendicular to a film surface and having an invariable magnetization direction;
a tunnel barrier layer provided between the recording layer and the reference layer;
a functional layer provided on a surface of the recording layer, which is opposite to a surface of the recording layer where the spacing layer is provided, wherein the functional layer contains a rocksalt crystal structure having the (100) plane parallel to the substrate plane and with lattice parameter along its {110} direction being larger than the bcc(body-centered cubic)-phase Co lattice parameter along {100} direction;
and an electrode layer provided on a surface of the functional layer, which is opposite to a surface of the functional layer where the recording layer is provided.

### FIRST EMBODIMENT

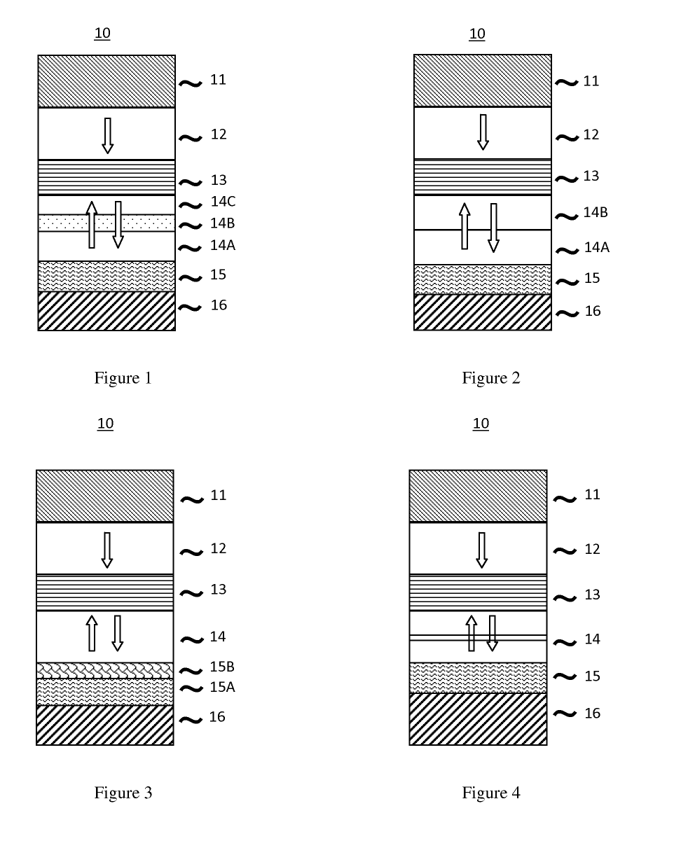

FIG. 1 is a cross-sectional view showing a configuration of an MTJ element 10 as a MTJ element according to the first embodiment. The MTJ element 10 is configured by stacking an upper electrode 11, a reference layer 12, a tunnel barrier layer 13, a recording layer 14, a functional layer 15, and a bottom electrode layer 16 in this order from the top.

The recording layer 14 and reference layer 12 each are made of a ferromagnetic material, and have uni-axial magnetic anisotropy in a direction perpendicular to a film surfaces. Further, directions of easy magnetization of the recording layer 14 and reference layer 12 are also perpendicular to the film surfaces. In another word, the MTJ element 10 is a perpendicular MTJ element in which magnetization directions of the recording layer 14 and reference layer 12 face in directions perpendicular to the film surfaces. A direction of easy magnetization is a direction in which the internal magnetic energy is at its minimum where no external magnetic field exists. Meanwhile, a direction of hard magnetization is a direction which the internal energy is at its maximum where no external magnetic field exists.

The recording layer 14 has a variable (reversible) magnetization direction. The reference layer 12 has an invariable (fixing) magnetization direction. The reference layer 12 is made of a ferromagnetic material having a perpendicular magnetic anisotropic energy which is sufficiently greater than the recording layer 14. This strong perpendicular magnetic anisotropy can be achieved by selecting a material, configuration and a film thickness, such as TbCoFe(10 nm)/CoFeB(2 nm), or CoPd(10 nm)/CoFeB(2 nm), or multilayer such as (Co/Pd)n/CoFeB(2 nm). In this manner, a spin polarized current may only reverse the magnetization direction of the recording layer 14 while the magnetization direction of the reference layer 12 remains unchanged. An MTJ element 10 which comprises a recording layer 14 having a variable magnetization direction and a reference layer 12 having an invariable magnetization direction for a predetermined write current can be achieved.

The tunnel barrier layer 13 is made of a metal oxide or nitride can be used, such as MgO, MgN, etc.

The functional layer 15 may serve to introduce surface perpendicular magnetic anisotropy of the recording layer 14. The functional layer 15 is made of an oxide (or nitride, chloride) layer which has a rocksalt crystalline as its naturally stable structure thereof will be described later.

An example configuration of the MTJ element 10 will be described below. The reference layer 12 is made of TbCoFe(10 nm)/CoFeB(2 nm). The tunnel barrier layer 13 is made of MgO(1 nm). The recording layer 14 is made of CoFeB(0.8 nm)/CoPd(2 nm)/CoFeB(1.2 nm). The functional layer 15 is made of MgO(2.5 nm). The bottom electrode layer 16 is made of Ta(20 nm)/Cu(20 nm)/Ta(20 nm). Each element written in the left side of “/” is stacked above an element written in the right side thereof.

In the recording layer, the first ferromagnetic sub-layer 14C is made of CoFeB(0.8 nm) and has a small surface perpendicular anisotropy from the interaction with its immediately adjacent rocksalt crystal MgO tunnel barrier layer. The second amorphous ferromagnetic sub-layer 14A is made of CoFeB(1.2 nm) immediately adjacent to the rocksalt crystal functional layer has a strong surface perpendicular anisotropy. The middle ferromagnetic layer 14B is made of CoPd(2 nm) which has a moderate crystal perpendicular anisotropy.

A perpendicular magnetization of the recording layer is achieved by the combination of the crystal perpendicular anisotropy and surface perpendicular anisotropy. Among these perpendicular anisotropies, the surface perpendicular anisotropy strength of the second sub-layer 14A can be manipulated through applying an electric field on the dielectric functional layer. Further as the electric field pointed upward from the top surface of the functional layer is strong enough, the surface perpendicular anisotropy of the second sub-layer 14A can changed into a surface in-plane anisotropy, which would directly cause a large reduction in the total perpendicular anisotropy in a recording layer, accordingly leading to a much reduced spin transfer current during a write operation.

### SECOND EMBODIMENT

FIG. 2 is a cross-sectional view showing an example configuration of the MTJ element 10 according to the second embodiment. The MTJ element 10 is configured by stacking an upper electrode 11, a reference layer 12, a tunnel barrier layer 13, a recording layer 14, a functional layer 15, and a bottom electrode layer 16 in this order from the top.

An example configuration of the MTJ element 10 will be described below. The reference layer 12 is made of TbCoFe(10 nm)/CoFeB(2 nm). The tunnel barrier layer 13 is made of MgO(1 nm). The recording layer 14 is made of Co2FeAl(2.5 nm)/CoFeB(1.2 nm). The functional layer 15 is made of MgO(2.5 nm). The bottom electrode layer 16 is made of Ta(20 nm)/Cu(20 nm)/Ta(20 nm). Each element written in the left side of “/” is stacked above an element written in the right side thereof.

In the recording layer, the first ferromagnetic sub-layer is a half-metal Heusler alloy film Co2FeAl(2.5 nm) and has a small surface perpendicular anisotropy from the interaction with its immediately adjacent rocksalt crystal MgO tunnel barrier layer. The second amorphous ferromagnetic sub-layer CoFeB(1.2 nm) immediately adjacent to the rocksalt crystal functional layer has a strong surface perpendicular anisotropy. An optional insertion layer can be added between the first and the second magnetic sub-layers for better crystal structure and thermal property of a Heusler alloy film.

### THIRD EMBODIMENT

FIG. 3 is a cross-sectional view showing an example configuration of the MTJ element 10 according to the third embodiment. The MTJ element 10 is configured by stacking an upper electrode 11, a reference layer 12, a tunnel barrier layer 13, a recording layer 14, a buffer layer 15B, a functional layer 15A, and a bottom electrode layer 16 in this order from the top.

An example configuration of the MTJ element 10 will be described below. The reference layer 12 is made of TbCoFe(10 nm)/CoFeB(2 nm). The tunnel barrier layer 13 is made of MgO(1 nm). The recording layer 14 is made of CoFeB(1.5 nm). The buffer layer 15B is made of MgLiO(1.5 nm). The functional layer 15A is made of MgO(2.5 nm). The bottom electrode layer 16 is made of Ta(20 nm)/Cu(20 nm)/Ta(20 nm). Each element written in the left side of “/” is stacked above an element written in the right side thereof. The buffer layer is a rocksalt crystal MgO with Li doping agent, which is a conductive layer. The doping agent can be also selected from other metal elements, such as Cr, Ti, etc.

### FOURTH EMBODIMENT

FIG. 4 is a cross-sectional view showing an example configuration of the MTJ element 10 according to the fourth embodiment. The MTJ element 10 is configured by stacking an upper electrode 11, a reference layer 12, a tunnel barrier layer 13, a recording layer 14, a functional layer 15, and a bottom electrode layer 16 in this order from the top.

An example configuration of the MTJ element 10 will be described below. The reference layer 12 is made of TbCoFe(10 nm)/CoFeB(2 nm). The tunnel barrier layer 13 is made of MgO(1 nm). The recording layer 14 is made of an anti-parallel structure CoFeB (0.8 nm)/CoFe(0.3 nm)/Ru(0.8 nm)/CoFe(0.3 nm)/CoFeB (1.2 nm). The functional layer 15 is made of MgO(2.5 nm). The bottom electrode layer 16 is made of Ta(20 nm)/Cu(20 nm)/Ta(20 nm). Each element written in the left side of “/” is stacked above an element written in the right side thereof.

While certain embodiments have been described above, these embodiments have been presented by way of example only, and are not intended to limit the scope of the inventions. For an example, the perpendicular MTJ element in each embodiment may have reversed layer-by-layer sequence. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A magnetoresistive element comprising:
a recording layer having magnetic anisotropy in a direction perpendicular to a film surface and having a variable magnetization direction;
a reference layer having magnetic anisotropy in a direction perpendicular to a film surface and having a first invariable magnetization direction;
a tunnel barrier layer provided between the recording layer and the reference layer;
a functional layer provided on a surface of the recording layer, which is opposite to a surface of the recording layer where the spacing layer is provided, wherein the functional layer contains a rocksalt crystal structure having the (100) plane parallel to the substrate plane and with lattice parameter along its {110} direction being larger than the bcc(body-centered cubic)-phase Co lattice parameter along {100} direction;
and an electrode layer provided on a surface of the functional layer, which is opposite to a surface of the functional layer where the recording layer is provided.

2. The element of claim 1, wherein said functional layer comprises a single layer or multi-layer of oxide, or nitride, or chloride having rocksalt crystal structure and containing at least one element selected from Na, Li, Mg, Ca, Zn, Cd, In, Sn, Cu, Ag, preferred to be naturally stable rocksalt metal oxide selected from MgO, MgN, CaO, CaN, MgZnO, CdO, CdN, MgCdO, CdZnO.

3. The element of claim 1, wherein said recording layer is made of a multilayer structure having a first magnetic sub-layer immediately adjacent to said tunnel barrier layer, a second magnetic sub-layer having an interface interaction induced perpendicular anisotropy and immediately adjacent to said functional layer, an optional middle magnetic sub-layer having a crystal perpendicular anisotropy.

4. The element of claim 3, wherein said second magnetic sub-layer is made of amorphous ferromagnetic material, preferred to be a single layer selected from CoFeB, CoB, FeB, CoFeNiB, NiFeB, CoNiB, wherein Boron content is at least 10% and less than 35%.

5. The element of claim 3, wherein said first magnetic sub-layer is made of ferromagnetic material, preferred to be s single layer selected from CoFe, Fe, FeNi, CoNi, CoFeB, CoB, FeB, CoFeNiB, NiFeB, CoNiB.

6. The element of claim 3, wherein said first magnetic sub-layer is made of a half-metal Heusler alloy, preferred to be selected from Co2MnSi, Co2FeAl, Co2FeSi, Co2MnAl.

7. The element of claim 3, wherein said middle magnetic layer is made of ferromagnetic material having a crystal perpendicular anisotropy, preferred to be selected from an alloy containing at least one element from Co, Fe and containing at least one element from Pd, Pt.

8. The element of claim 3, wherein said recording layer comprising an optional insertion layer between said middle magnetic sub-layer and said second magnetic sub-layer, preferred to be selected from Ta, W, Ti, Cr, Zr, Nb, Hf, V, Mo, Pt, Pd, Au, Ag, Al.

9. The element of claim 1, further comprising an optional buffer layer between said functional layer and said recording layer having a rocksalt crystal with doping agent, wherein the rocksalt crystal is preferred to be selected from MgO, MgN, CaO, CaN, MgZnO, CdO, CdN, MgCdO, CdZnO, and the doping agent is preferred to be selected from Cr, Al, B, Si, P, S, Cu, Zn, Cd, In, Sn, Ag, Be, Ca, Li, Na, Sc, Ti, Rb, V, Mn.

10. The element of claim 1, further comprising an optional buffer layer between said functional layer and said recording layer having a super-lattice structure L21 or B2, preferred to be selected from CuZn, AuCd, AlNi, NiZn, AlFe, LiTi, Co2MnSi.

11. The element of claim 1, wherein said recording layer is made of a synthetic anti-parallel structure, preferred to be CoFeB/CoFe/Ru/CoFe/CoFeB.
